(19) United States
(12) Patent Application Publication
(10) Pub. No.: US 2007/0000437 A1
(43) Pub. Date: Jan. 4, 2007

(54) Porous structure treatment system

(76) Inventors: Edward E. Young JR., Hobe Sound, FL (US); Fredrick D. Shaffer, Jupiter, FL (US)

Correspondence Address: AKERMAN SENTERFITT, P.O. BOX 3188, WEST PALM BEACH, FL, 33402-3188, US

(21) Appl. No.: 11/172,043

(22) Filed: Jun. 30, 2005

(51) Int. Cl. C23C 14/00; B05C 5/00

(52) U.S. Cl. 118/50; 118/313

(57) ABSTRACT

A porous material injection system for injecting protective material into a porous material. The porous material injection system may include an injection hood formed from a hood structure having a top plate, first and second cavities. During use, a vacuum may be formed in the first cavity to attach the injection hood to the porous material, and a protective material may be injected through a plurality of orifices in the second cavity and into the porous material. In another embodiment, the injection hood may be attached to a porous material with a mechanical connector and the protective material may be injected through a plurality of orifices into the porous material.

### FIELD OF THE INVENTION

This invention is directed generally to material preservation systems, and more particularly to porous material injection systems for the preservation of the porous material.

### BACKGROUND

Structural supports and other items are often formed from materials having embedded supports. For instance, structures, such as pilings, columns, decks, bridges, docks, walls, and other items formed from concrete and other materials often are reinforced with internal steel supports. Common building materials such as concrete, marble, masonry, brick, stone, and wood are porous. Exposure to the outside environment or an industrial environment typically leads to the decay of the building materials themselves and to the reinforcement materials contained within these materials. For example, reinforcing steel embedded within concrete suffer from corrosion and oxidation that results from exposure to water and air in the outside environment. Pollutants in the atmosphere also damage the building materials.

Attempts have been made to curb this destruction and preserve the materials. For instance, preservative materials have been applied to the surface of a building material via brush, roller, sprayer, or pressure injection. Coating only the surface can, in some cases, create internal stresses caused by the change of pressure and the presence of moisture within the material, thereby causing additional damage to the material. Other methods include systems in which holes are drilled into the material to be treated, and preservative materials are injected into the materials. This method is time consuming and is an invasive procedure.

Another procedure has been developed, as discussed in U.S. Published Patent Application No. 2004/0258846. This procedure involves injecting a preservative material into a porous material under a pressure of between about 10 pounds per square inch and about 15 pounds per square inch. The material is injected using an injection hood having an outer vacuum cavity 1 and an inner injection cavity 2, as shown in FIG. 1. The preservative material is injected through hole 3 in the inner injection cavity 2. An outer wall 5 defines a portion of the outer vacuum cavity 1 and includes a seal 6, as shown in cross-section in FIG. 2. The inner wall defines the inner injection cavity 2 and includes a seal 7, which has the cross-section shown in FIG. 2. During operation, a vacuum is initially formed through both ports 4 and 8 to secure the hood. Port 4 is then shut off leaving the outer vacuum cavity 1 to attach the injection hood to the porous material. A preservative material is injected into the porous material through port 3. The preservative material injected is a calcium based fluid containing surfactant.

The procedure and device disclosed in U.S. Published Patent Application No. 2004/0258846 is frought with problems. First, the preservative material causes the formation of foam that inhibits proper operation of the equipment and requires time consuming cleanup. Second, the injection hood cannot inject the preservative material at a pressure exceeding about 15 pounds per square inch without the vacuum in the outer vacuum cavity being lost, thereby detaching the injection hood from the porous material. Thus, the efficiency of the device is currently limited by the strength of the vacuum created in the outer vacuum cavity and the seals. Third, the position of the injection port 3 does not facilitate efficient injection of the preservative material into the porous material adjacent to the inner injection cavity 2. Rather, the preservative material collects within the inner injection cavity 2 without being injected into the porous material. The single injection port 3 creates dead zones within the inner injection cavity 2. Thus, a system and device are needed that can facilitate the efficient injection of preservative materials into a porous material.

### SUMMARY OF THE INVENTION

This invention relates to a porous material injection system configured to inject materials into a porous material such as, but not limited to concrete, wood, masonry, stone, marble, and other materials having embedded members to support the porous materials. The porous material may be a support surface, a piling, a column, a wall, submerged structures, and other structures. The porous material may be a flat surface, curved surface, or have another shape. The porous material injection system may be configured to inject a protective material into a porous material to substantially reduce or eliminate corrosion of steel reinforcing members, cracking, spaulling, crumbling, and erosion of the porous material. The protective material may be any fluid capable of being injected without producing foam in an amount that impedes uptake of the protective material into the porous material and operation of the injection hood. One such material having this characteristic is PERMATREAT produced by Shore Chemical, Inc., Pittsburg, Pa.

The porous material injection system may include an injection hood for injecting a protective material into the porous material. The injection hood may be formed from a hood structure having a top plate and at least one side wall extending out of a plane of the top plate and forming a first cavity. A sealing rib may extend from the hood structure of the top plate and may form a second cavity in the hood structure and within the first cavity. A plurality of injection ports may extend through the top plate of the hood structure and be positioned in the second cavity. The injection hood may include at least one vacuum system orifice positioned in the top plate and in the first cavity and be adapted to be coupled to a vacuum system. A fluid transport conduit may be coupled to the plurality of injection ports in the second cavity. A first seal may be coupled to the at least one side wall and configured to seal the first cavity to a surface of a porous material to be injected with a protective material, and a second seal may be coupled to the sealing rib forming the second cavity and configured to seal the second cavity to the surface of the porous material to be injected with a protective material. The first cavity may also be configured to contain a vacuum in the first cavity.

The injection hood may also include an outer seal support rib positioned in close proximity to the at least one side wall and extending from the top plate to support the first seal such that the first seal fits between the seal support rib and the at least one side wall. The sealing rim forming the second cavity may be formed from an outer sealing rib and an inner sealing rib separated a distance sufficient to position the second seal between the outer sealing rib and the inner sealing rib. The first and second seals may be positioned in the same plane for attachment to a flat surface or may be positioned in different planes for attachment to curved surfaces. In at least one embodiment, the first and second seals may be formed from closed cell neoprene foam. The first and second seals may also have a flat outer contact surface for contact with a porous material.

The porous material injection system may include at least one vacuum system coupled to the vacuum orifice positioned in the top plate and in the second cavity and adapted to be coupled to a vacuum system. A relief valve may be coupled to the second cavity for controlling the vacuum and purging excess protective material from the second cavity. The porous material injection system may include a compressed air source coupled to the fluid transport conduit and a fluid pump in communication with the compressed air source for moving the protective material from a storage tank to the injection hood. The storage tank may be in communication with the fluid pump for supplying a protective material to the injection hood.

The porous material injection system may also include a movable support system having sufficient storage capacity to support components of the system, such as, but not limited to, the storage tank, the vacuum source, the fluid pump, the compressed air source, and the injection hood. In at least one embodiment, the movable support system may be a trailer with a plurality of wheels. In an embodiment supported by the removable support system, the injection hood may be positioned proximate to a lower surface of the trailer to enable the injection hood to be lowered from the trailer and placed in contact with a porous material to be treated. The injection hood may be positioned under the movable support system with an injection hood engagement system. The injection hood engagement system may include one ore more hydraulic, pneumatic, or other actuators coupled to the injection hood and to the trailer for placing the injection hood in contact with a porous material to be treated.

The porous material injection system may be used to inject a fluid material into a porous material. The process includes attaching an injection hood to a porous material. The injection hood may be attached to the porous material with a mechanical connector system, a vacuum, with both systems, or with another method. The protective material may be passed from a storage tank through a pump, through a conduit, and into a fluid transport conduit in communication with the injection ports in the injection hood. The protective material may be injected through the plurality of injection ports and into the porous material. In embodiments having only a single cavity in the injection hood, the protective material may be injected into the first cavity. However in embodiments of the injection hood having an first outer cavity and a second inner cavity, a vacuum may be formed in the first outer cavity and the protective material may be injected into the second inner cavity.

The protective material may be injected through the plurality of injection ports and into the porous material at a pressure of between about 90 pounds per square inch and about 120 pounds per square inch. Injecting the protective material at this pressure results in superior uptake by the porous material of the protective material. In at least one embodiment, a dye may be added to the protective material before injection to track the progression of the protective material in the porous material.

The protective material may be injected into the porous material for a predetermined time period. After injection has ceased, the excess protective material on an outer surface of the porous material may be withdrawn with a vacuum and relief valve and deposited in a storage tank. The protective material may be passed through a carbon filter before being deposited into the storage tank.

An advantage of this invention is that the plurality of injection ports in the top plate facilitate uniform injection of a protective material into a porous material throughout the cavity into which the protective material is injected.

Another advantage of this invention is that the protective material may be injected into a porous material at a pressure of between about 90 pounds per square inch and about 120 pounds per square inch. Injection of the protective material within this range yields superior penetration of the protective material into the porous material.

Yet another advantage of this invention is that the injection hood may be configured to be movably attached to an underside of a movable support system such that the injection hood may be attached to a flat surface, such as a road or bridge surface, to inject the porous material with a protective material. Such a configuration enables a flat surface to be injected with a protective material automatically and conveniently.

Another advantage of this invention is that the porous material injection system may inject a protective material containing a dye to track the penetration of the protective material into the porous material.

These and other embodiments are described in more detail below.

### BRIEF DESCRIPTION OF THE DRAWINGS

The accompanying drawings, which are incorporated in and form a part of the specification, illustrate embodiments of the presently disclosed invention and, together with the description, disclose the principles of the invention.

FIG. 1 is a perspective view of a bottom surface of a conventional injection hood.

FIG. 2 is a cross-sectional view of a conventional seal usable to seal the injection hood to a porous material taken at section line 2-2 in FIG. 1.

FIG. 3 is a perspective view of a porous material injection system having aspects of this invention and positioned on a movable support system.

FIG. 4 is a perspective view of an injection hood of the invention.

FIG. 5 is a bottom plan view of the injection hood of FIG. 4.

FIG. 6 is a top plan view of the injection hood of FIG. 4.

FIG. 7 is a cross-sectional view of injection hood taken at 7-7 in FIG. 4.

FIG. 8 is bottom plan view of an alternative embodiment of the injection hood.

FIG. 9 is a perspective view of the injection hood of the invention with a connector system.

FIG. 10 is a perspective view of an embodiment of the invention with a connector system and two injection hoods.

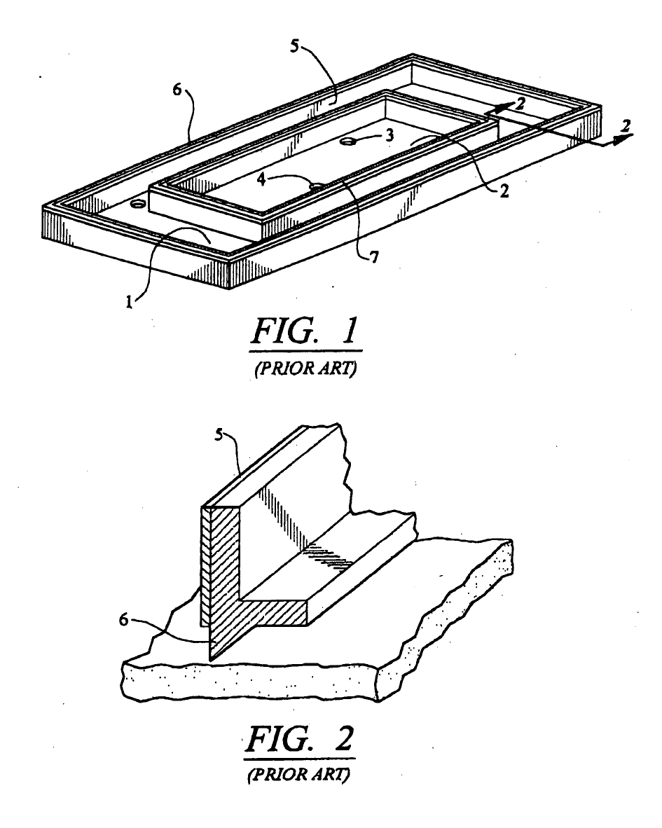

### DETAILED DESCRIPTION OF THE INVENTION

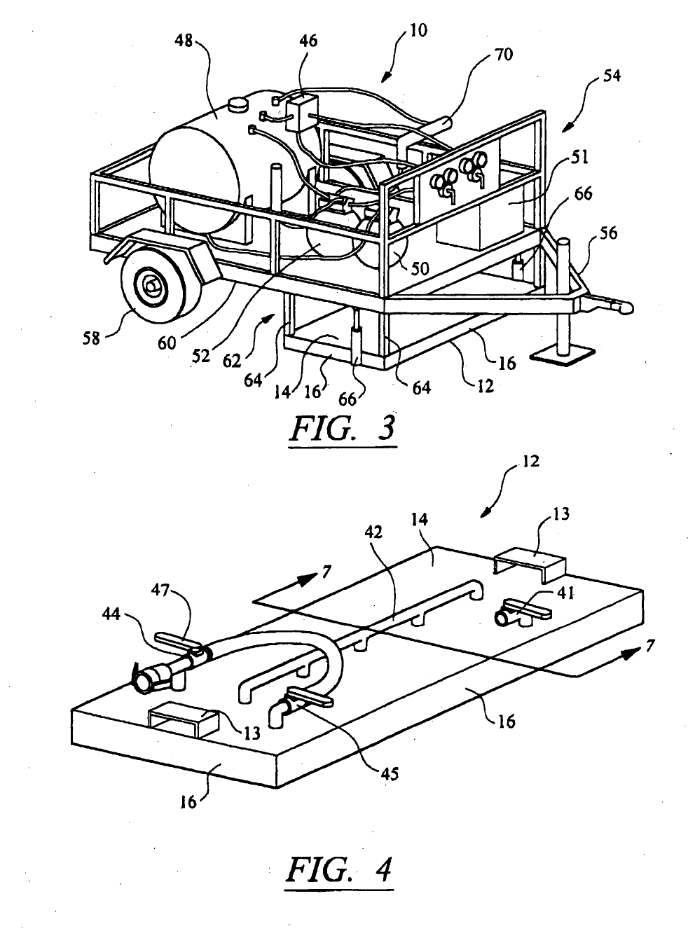

As shown in FIGS. 3-10, this invention is directed to a porous material injection system 10 configured to inject materials into a porous material such as, but not limited to concrete, wood, masonry, stone, marble, and other materials having embedded members. The porous material may be configured to be a support surface, a piling, a column, a wall, submerged structures, and other structures. The porous material may be a flat surface, a curved surface, or have another shape. The porous material injection system 10 may be configured to inject a protective material into a porous material to substantially reduce or eliminate corrosion of steel reinforcing members, cracking, spaulling, crumbling, and erosion of the porous material.

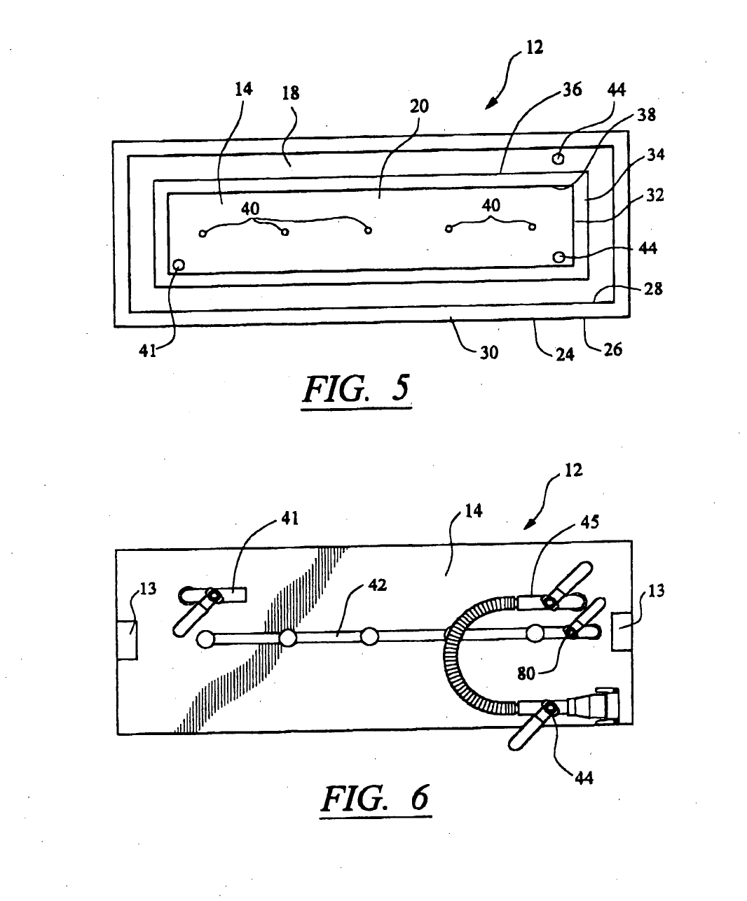

The porous material injection system 10 may include an injection hood 12 configured to inject a protective material into a porous material. The injection hood may include handles 13 facilitating lifting the hood 12. As shown in FIGS. 4-7, the injection hood 12 may be formed from any configuration capable of efficiently injecting a protective material into a porous material. In at least one embodiment, the injection hood 12 may be formed from a top plate 14 and at least one side wall 16. The side wall 16 may extend from the top plate 14 a distant sufficient to form a first cavity 18, as shown in FIGS. 5 and 8. The first cavity 18 may be configured to receive a protective material to be injected into a porous material via fluid valve 80. The injection hood 12 may be configured to be attached to a flat surface, a curved surface, or surfaces having other shapes.

In another embodiment, as shown in FIG. 5, the injection hood 12 may also include a second cavity 20 positioned within the first cavity 18, thereby forming the first cavity 18, which is an outer cavity, and the second cavity 20, which is an inner cavity. The second cavity 20 may be formed with a seal rib 22 positioned in the first cavity 18 and extending from the top plate 14. The outer cavity 18 may be used as a vacuum cavity to attach the injection hood 12 to a porous material, and the inner cavity 20 may be used as an injection cavity to inject the protective material into the porous material via fluid valve 80, or vice versa. In the embodiment shown in FIG. 8, the injection hood 12 includes only a single first cavity 18 for injecting a protective material into a porous material. In this embodiment, the injection hood 12 may be attached to the porous material using a mechanical system 68 as described below.

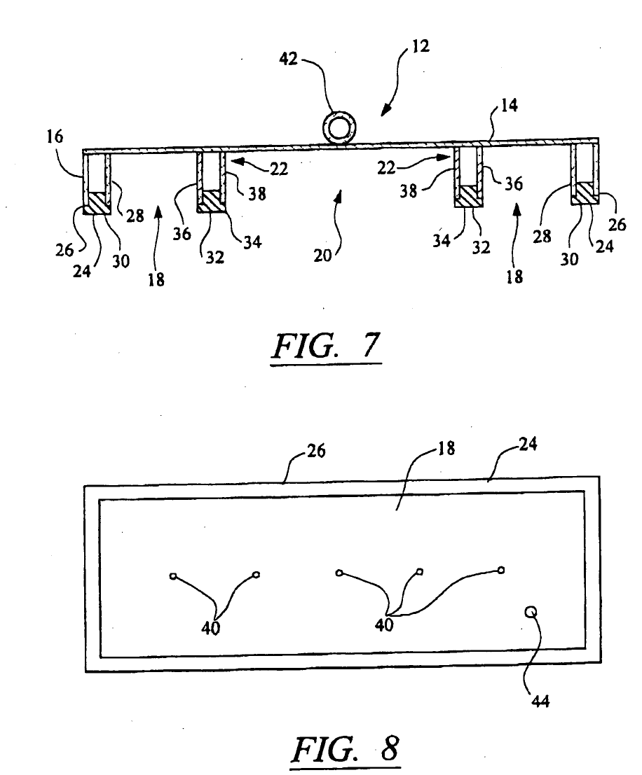

The injection hood 12 may include seals for sealing the injection hood 12 to a porous surface. As shown in FIGS. 5 and 7, the injection hood may include a first seal 24 attached to an outer edge 26 of the side wall 16. The seal 24 may be formed from materials such as, but not limited to closed cell neoprene foam. The seal 24 may be extend from the outer edge of the side wall 16 and may have a generally rectangular cross-section. The seal 24 may include an outer surface 30 that is substantially flat. The seal 24 may be supported by an outer seal support rib 28. The outer seal support rib 28 may extend from the top plate 14, the side wall 16, or other appropriate structure. The outer seal support rib 28 may extend to within close proximity of an outermost surface 30 of the first seal 24 to facilitate separation of the first cavity 18 from the environment outside of the injection hood 12 when the injection hood 12 is attached to a porous material and attachment of the hood 12 to the porous material. The outer seal support rib 28 supports the first seal 24 to prevent the first seal 24 from losing seal against a porous material during use.

The injection hood 12 may also include a second seal 32 for sealing the second cavity 20 to a porous surface. The second seal 32 may extend from the sealing rib 22. In at least one embodiment, an outermost surface 34 of the second seal 32 may be positioned in a plane in which the outermost surface 30 of the first seal 24 rests. The seal 24 may include an outer surface 30 that is substantially flat. The second seal 32 may be supported by the sealing rib 22. The second seal 32 may prevent the second seal 32 from losing seal against a porous material during use. As shown in FIG. 7, the sealing rib 22 may be formed from an outer sealing rib 36 and an inner sealing rib 38 extending from the top plate 14. Either of the outer sealing rib 36 of the inner sealing rib 38, or both, may extend from the top plate 14 to within close proximity of the outermost surface 34 of the second seal 32 to support the second seal 32 and prevent the second seal 32 from losing seal against a porous material during use. The second seal 32 may have a generally rectangular cross-section or other appropriate shape. The second seal 32 may be formed from materials such as, but not limited to closed cell neoprene foam. In at least one embodiment, as shown in FIG. 5, the outer sealing rib 36 and an inner sealing rib 38 may be formed in a generally rectangular shape or other appropriate shape.

The injection hood 12 may also include a plurality of injection ports 40 for injecting a protective material into a porous material. The injection ports 40 may extend through the top plate 14. The injection ports 40 may be coupled together with a fluid transport conduit 42. The fluid transport conduit 42 may be positioned outside of the top plate 14 or contained within the top plate 14. The injection ports 40 may be positioned within the injection hood 12 to facilitate injection of a protective material into a porous material. In at least one embodiment, the injection ports 40 may be positioned generally parallel to each other. The injection ports 40 may or may not be positioned equidistant from each other. As shown in one embodiment in FIG. 5, the injection hood 12 may include five injection ports 40 and have a diameter of about one half of an inch. The number and size of the injection ports 40 may vary depending on the intended application and other factors. Injection hood 12 may also include a second cavity valve 45 coupled to the second cavity 20 through the top plate 14 to allow for the removal of remaining material from the second cavity 20.

The injection hood 12 may also include one or more vacuum orifices 44 in the first cavity 18 for attaching the injection hood 12 to a porous surface by creating a creating a vacuum in the first cavity 18. The vacuum orifices 44 and valves 41, 45, 80 may be appropriately sized and positioned within the top plate 14. A vacuum orifice 44 coupled to a valve 45 may be positioned within the second cavity 20 to remove excess protective material not injected into a porous material. A vacuum orifice 44 coupled to a valve 47 may be positioned within the first cavity 18 create a vacuum in the first cavity 18. The vacuum orifice 44 in the second cavity 20 may be coupled to a vacuum orifice 44 in the first cavity 18, wherein the vacuum is controlled with one or more relief valves 45, 47. A relief valve 41 may be included for controlling the vacuum or material injection in the second cavity 20.

The porous material injection system 10 may also include a pump 46 for pumping a protective material from a storage tank 48 to the injection hood 12 via fluid valve 100. The pump 46 may be, but is not limited to, a pneumatic pump, an electric pump, a baffle pump, or other appropriate pump. The storage tank 48 may be sized appropriately for the application. For instance, the storage tank 48 may be sized between about five gallons and five hundred gallons, or even larger, depending on the application. The storage tank 48 may or may not be permanently affixed to the movable support system 54.

The porous material injection system 10 may also include a compressed air source 50 to operate pneumatic pump 46 and pneumatic actuators 66, if such actuators are used. The compressed air source 50 may be attached to the pump 46. The porous material injection system 10 may also include a vacuum source 52. The vacuum source 52 may be capable of establishing a vacuum in the first cavity 18 of between about 1 mmHg and about 760 mmHG.

In at least one embodiment, the components of the porous material injection system 10 may be positioned on a movable support system 54. The movable support system 54 may have sufficient storage capacity to store the storage tank 48, the vacuum source 52, the fluid pump 46, the compressed air source 50, a generator 51, and the injection hood 12. In at least one embodiment, as shown in FIG. 3, the movable support system 54 may be a trailer 56 having a plurality of wheels 58 and be configured to be pulled behind a vehicle. The trailer may be appropriately sized to support the components of the porous material injection system 10. In another embodiment, the movable support system 54 may be a self-propelled vehicle having an appropriate size and configuration.

In at least one embodiment, as shown in FIG. 3, one or more injection hoods 12 may be coupled to an underside 60 of the movable support system 54. The injection hood 12 may be attached to the movable support system 54 with an injection hood engagement system 62 capable of moving the injection hood 12 from a storage position proximate to the underside 60 of the trailer 56 to an injection position in contact with a porous material. In at least one embodiment, the injection hood engagement system 62 may be formed from a plurality of arms 64 and hydraulic, pneumatic or other actuators 66 capable of moving the injection hood 12 into contact with a porous surface. The injection hood 12 may be held in contact with the porous material without use of a vacuum, such as with the arms 64 and the weight of the trailer.

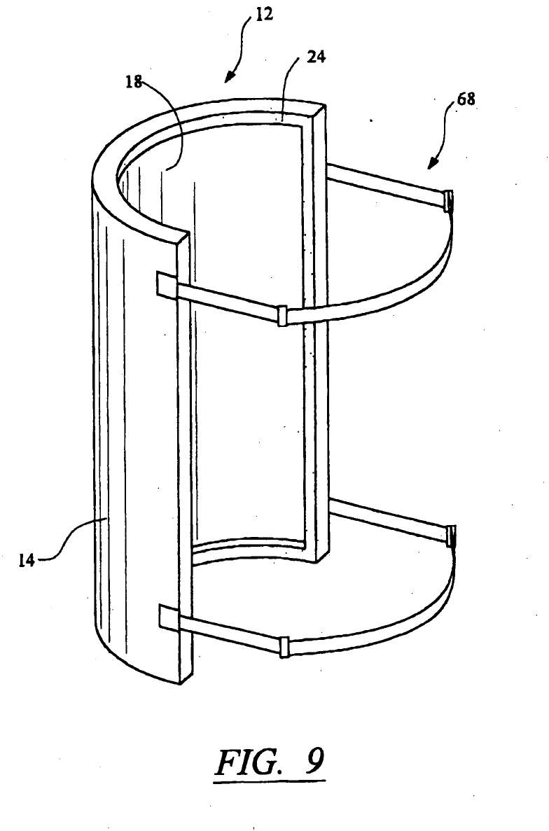

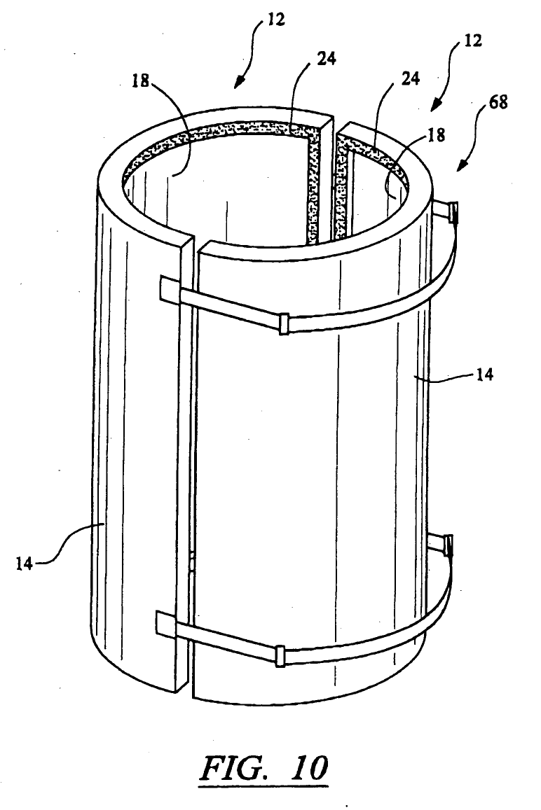

The porous material injection system 10 may also include a connector system 68, as shown in FIG. 9, for attaching the injection hood 12 to a porous material without use of a vacuum. The connector system 68 may enable the injection hood 12 to be attached to a column, piling, or other such structure. The connector system 68 may enable the injection hood 12 to be attached to surfaces in which formation of a vacuum is difficult or impossible. The connector system 68 may be formed from any system enabling the injection hood 12 to be attached to a porous material and to enable the porous material to be injected with a material emitted from the hood 12. In at least one embodiment, the connector system 68 may be formed from one or more arms 70 configured to attach the injection hood 12 to a column. The arms 70 may include an adjustment system, such as but not limited to, a threaded rod, an actuator, such as but not limited to a hydraulic actuator, a pneumatic actuator, or other appropriate actuator, or other appropriate system. The connector system 68 may be capable of attaching the injection hood 12 to a column with sufficient force to enable a material to be injected into the column. In at least one embodiment, as shown in FIG. 10, the porous material injection system 10 may include an injection hood 12 on each side of a column or other structure.

In an exemplary embodiment, the top plate 14 of the injection hood 12 may have a height of about 36 inches and a width of about 24 inches, and the sidewalls 16 may be about two inches in height. The thickness of the top plate 14 and the sidewalls 16 may be between about one thirty second of an inch and about one quarter of an inch. The plurality of injection orifices 40 may be coupled together with the fluid transport conduit 42 and may be coupled to a storage tank 48 for supplying a protective material to the injection hood 12 through fluid valve 80. The vacuum orifices 44 in the top plate 14 may be coupled to a vacuum source 52 with appropriate conduit. Valves (not shown) may be placed inline between the vacuum orifices 44 and the vacuum source 52 and between the injection orifices 40 and the storage tank 48. The system of conduits may have any appropriate configuration.

The porous material injection system 10 may be used for injecting a fluid into a porous material. In at least one embodiment, the porous material injection system 10 may be used for injecting a protective material into a porous material to protect support members within the porous material. In at least one embodiment, a protective material may be injected into reinforced concrete to substantially reduce, if not eliminate, corrosion of steel reinforcements within the concrete. The protective material preferably is a material that does not foam in an amount that impedes uptake of the protective material into the porous material and operation of the injection hood. The protective material may have a potassium base without a surfactant. One such material meeting this requirement is PERMATREAT that is produced by Shore Chemical, Pittsburgh, Pa. The viscosity of this material is approximately equal to the viscosity of water. In another embodiment, the protective material may include a dye to facilitate determining the amount of penetration of the protective material into the porous material. The dye may have a color that is easily distinguishable from the porous material into which that protective material is injected.

The injection hood 12 may be first attached to a porous material. In embodiments having a connector system 68, the connector system 68 may be positioned and actuated to attached the injection hood 12 to the porous material. In embodiments without the connector system 68, the injection hood may be attached to a porous material by creating a vacuum in the first cavity 18. The vacuum may be created by actuating a vacuum pump in fluid communication with the first cavity 18. A vacuum may be created initially in the second cavity 20 using second cavity valve 45 to facilitate attachment. The second cavity valve 44 may be closed once the vacuum in the first cavity is established. Once the injection hood 12 has been attached to the porous material, the protective material may be injected into the porous material by opening the fluid valve 80. The material may be drawn from a storage tank 48, passed through a conduit, and into the fluid transport conduit 42 in the injection hood 12. The pump 46 transports the protective material from the storage tank 48 to the injection hood 12 through fluid valve 80.

The protective material is then passed to the plurality of injection ports 40 in the second cavity 20 of the injection hood 12. The protective material is injected through the injection ports 40. The position of the ports 40 in the second cavity 20 facilitates uniform injection of the protective material into the porous material. The period of time of the injection of the protective material varies depending on factors such as the porosity of the porous material, the desired depth of injection of the protective material, the viscosity of the protective material, and other factors. In at least one embodiment, the protective material may be injected into the porous material at a pressure of between about 90 pounds per square inch and about 120 pounds per square inch and for a time period of between about 30 seconds and three minutes. In other embodiments, the protective material may be injected into the porous material at other pressures less than or greater than this range and for time periods of longer or shorter duration.

Once the protective material has been injected into the porous material for a desired period of time, the injection of the protective material is ceased, and the excess protective material on the surface of the porous material is removed. The excess protective material may be removed by opening a second cavity valve 45 and creating a vacuum in the second cavity 20. The excess protective material may be passed through a filter 70, such as, but not limited to an activated carbon filter. The excess protective material may be deposited in the storage tank 48 used to store the unused protective material or may be stored in another storage tank containing only used protective material.

The foregoing is provided for purposes of illustrating, explaining, and describing embodiments of this invention. Modifications and adaptations to these embodiments will be apparent to those skilled in the art and may be made without departing from the scope or spirit of this invention.

We claim:

1. A porous material injection system hood, comprising:
a hood structure having a top plate and at least one side wall extending out of a plane of the top plate and forming a first cavity;
a sealing rib extending from the hood structure of the top plate and forming a second cavity in the hood structure and within the first cavity;
a plurality of injection ports extending through the top plate of the hood structure and positioned in the second cavity;
a fluid transport conduit coupled to the plurality of injection ports in the second cavity;
a first seal coupled to the at least one side wall and configured to seal the first cavity to a surface of a porous material to be injected with a protective material; and
a second seal coupled to the sealing rib forming the second cavity and configured to seal the second cavity to the surface of the porous material to be injected with a protective material.

2. The porous material injection system hood of claim 1, further comprising an outer seal support rib positioned in close proximity to the at least one side wall and extending from the top plate to support the first seal such that the first seal fits between the seal support rib and the at least one side wall.

3. The porous material injection system hood of claim 1, wherein the sealing rib is formed from an outer sealing rib and an inner sealing rib separated a distance sufficient to position the second seal between the outer sealing rib and the inner sealing rib.

4. The porous material injection system hood of claim 1, further comprising at least one vacuum system orifice positioned in the top plate and in the second cavity and adapted to be coupled to a vacuum system.

5. The porous material injection system hood of claim 1, further comprising at least one vacuum system orifice positioned in the top plate and in the first cavity and adapted to be coupled to a vacuum system.

6. The porous material injection system hood of claim 1, wherein the first and second seals are formed from closed cell neoprene foam.

7. The porous material injection system hood of claim 1, further comprising an outer seal support rib positioned in close proximity to the at least one side wall and extending from the top plate to support the first seal such that the first seal fits between the outer seal support rib and the at least one side wall.

8. The porous material injection system of claim 1, further comprising a relief valve coupled to the second cavity to enable injection fluids to be removed from the surface of the porous material.

9. A porous material injection system hood, comprising:
a hood structure having a top plate and at least one side wall extending out of a plane of the top plate and forming a first cavity;
a plurality of injection ports extending through the top plate of the hood structure and positioned in the second cavity;
a first seal coupled to the at least one side wall and configured to seal the first cavity to a surface of a porous material to be injected with a protective material; and
a connector adapted to attach the hood structure to a porous material to inject a protective material into the porous material.

10. The porous material injection system hood of claim 9, further comprising a sealing rib extending from the hood structure of the top plate and forming a second cavity in the hood structure and within the first cavity and a second seal coupled to the sealing rib forming the second cavity and configured to seal the second cavity to the surface of the porous material to be injected with a protective material.

11. The porous material injection system hood of claim 10, wherein the sealing rib is formed from an outer sealing rib and an inner sealing rib separated a distance sufficient to position the second seal between the outer sealing rib and the inner sealing rib.

12. The porous material injection system hood of claim 10, further comprising at least one vacuum system orifice positioned in the top plate and in the second cavity and adapted to be coupled to a vacuum system.

13. The porous material injection system hood of claim 9, further comprising an outer seal support rib positioned in close proximity to the at least one side wall and extending from the top plate to support the first seal such that the first seal fits between the outer seal support rib and the at least one side wall.

14. The porous material injection system hood of claim 9, further comprising at least one vacuum system orifice positioned in the top plate and in the first cavity and adapted to be coupled to a vacuum system.

15. The porous material injection system hood of claim 9, wherein the first and second seals are formed from closed cell neoprene foam.

16. The porous material injection system of claim 9, further comprising a relief valve coupled to the second cavity to enable injection fluids to be removed from the surface of the porous material.

17. A porous material injection system, comprising:
an injection hood, comprising:
a hood structure having a top plate and at least one side wall extending out of a plane of the top plate and forming a first cavity;
a plurality of injection ports extending through the top plate of the hood structure and positioned in the first cavity;
at least one vacuum hole extending through the top plate of the hood structure and positioned in the first cavity;
a fluid transport conduit coupled to the plurality of injection ports in the second cavity;
a first seal coupled to the at least one side wall and configured to seal the first cavity to a surface of a porous material to be injected with a protective material; and
a compressed air source coupled to the fluid transport pump;
a fluid pump in communication with the compressed air source;
a vacuum source coupled to the at least one vacuum hole; and
a storage tank in communication with the fluid pump for supplying a protective material to the injection hood.

18. The porous material injection system of claim 17, further comprising a sealing rib extending from the hood structure of the top plate and forming a second cavity in the hood structure and within the first cavity and a second seal coupled to the sealing rib forming the second cavity and configured to seal the second cavity to the surface of the porous material to be injected with a protective material.

19. The porous material injection system of claim 18, further comprising a movable support system having sufficient storage capacity to support the storage tank, the vacuum source, the fluid pump, the compressed air source, and the injection hood.

20. The porous material injection system of claim 19, wherein the movable support system comprises a trailer with a plurality of wheels.

21. The porous material injection system of claim 19, wherein the movable support system comprises a self-propelled vehicle.

22. The porous material injection system of claim 19, wherein the injection hood is positioned proximate to a lower surface of the movable support system to enable the injection hood to be lowered from the movable support system and placed in contact with a porous material to be treated.

23. The porous material injection system of claim 22, further comprising a hydraulic actuation system coupled to the injection hood and to the trailer for placing the injection hood in contact with a porous material to be treated.

24. The porous material injection system of claim 18, wherein the sealing rib is formed from an outer sealing rib and an inner sealing rib separated a distance sufficient to position the second seal between the outer sealing rib and the inner sealing rib.

25. The porous material injection system of claim 18, further comprising at least one vacuum system orifice positioned in the top plate and in the second cavity and adapted to be coupled to a vacuum system.

26. The porous material injection system of claim 17, further comprising an outer seal support rib positioned in close proximity to the at least one side wall and extending from the top plate to support the first seal such that the first seal fits between the seal support rib and the at least one side wall.

27. The porous material injection system of claim 17, wherein the first and second seals are formed from closed cell neoprene foam.

28. The porous material injection system of claim 17, further comprising a carbon filter coupled in line with the storage tank to filter excess protective fluids collected from a surface of the porous material.

29. A method of treating a porous material, comprising:
attaching an injection hood to a porous material, wherein the injection hood comprises:
a hood structure having a top plate and at least one side wall extending out of a plane of the top plate and forming a first cavity;
a plurality of injection ports extending through the top plate of the hood structure and positioned in the first cavity;
at least one vacuum hole extending through the top plate of the hood structure and positioned in the first cavity;
a fluid transport conduit coupled to the plurality of injection ports in the second cavity;
a first seal coupled to the at least one side wall and configured to seal the first cavity to a surface of a porous material to be injected with a protective material;
passing a protective material through a pump;
injecting the protective material through the plurality of injection ports and into the porous material.

30. The method of treating a porous material of claim 29, wherein attaching the injection hood to a porous material comprises using a mechanical connector to attach the injection hood to a porous material.

31. The method of treating a porous material of claim 29, wherein attaching an injection hood to a porous material comprises attaching an injection hood having a sealing rib extending from the hood structure of the top plate and forming a second cavity in the hood structure and within the first cavity and having a second seal coupled to the sealing rib forming the second cavity and configured to seal the second cavity to the surface of the porous material to be injected with a protective material.

32. The method of treating a porous material of claim 31, wherein attaching an injection hood to a porous material comprises placing the injection hood in contact with the porous material such that the first and second seals contact the porous material and forming a vacuum in the first cavity.

33. The method of treating a porous material of claim 31, wherein injecting the protective material through the plurality of injection ports and into the porous material comprises injecting the protective material into the second cavity.

34. The method of treating a porous material of claim 29, wherein injecting the protective material through the plurality of injection ports and into the porous material comprises injecting the protective material at a pressure of between about 90 pounds per square inch and about 120 pounds per square inch.

35. The method of treating a porous material of claim 29, wherein injecting the protective material through the plurality of injection ports and into the porous material comprises injecting a protective material containing a dye usable to visually track progression of the protective material through the porous material.

36. The method of treating a porous material of claim 29, further comprising withdrawing excess protective material from an outer surface of the porous material with a vacuum and depositing the material in a storage tank.

37. The method of treating a porous material of claim 35, further comprises passing the protective material through a carbon filter before being deposited into a storage tank.

38. The method of treating a porous material of claim 29, wherein injecting the protective material through the plurality of injection ports and into the porous material comprises injecting a protective material that is capable of being injected into a porous material at a pressure range of between about 90 pounds per square inch and about 120 pounds per square inch without producing foam in an amount that impedes uptake of the protective material into the porous material and operation of the injection hood.

39. The method of treating a porous material of claim 29, wherein injecting the protective material through the plurality of injection ports and into the porous material comprises injecting a protective material having a potassium base without a surfactant.
